(19) United States
(12) Patent Application Publication
(10) Pub. No.: US 2014/0202747 A1
(43) Pub. Date: Jul. 24, 2014

(54) CIRCUIT BOARD AND MANUFACTURING METHOD THEREOF

(71) Applicant: ELITES ELECTRONICS CORP., New Taipei City (TW)

(72) Inventor: Jung-Yu Peng, New Taipei City (TW)

(73) Assignee: ELITES ELECTRONICS CORP., New Taipei City (TW)

(21) Appl. No.: 13/748,589

(22) Filed: Jan. 24, 2013

(51) Int. Cl. H05K 3/00; H05K 3/40; H05K 1/09; H05K 1/11; H05K 1/03

(52) U.S. Cl. CPC H05K 3/005; H05K 1/116; H05K 1/03; H05K 1/092; H05K 3/4084
USPC 174/257; 174/266; 174/258; 29/853; 29/852

(57) ABSTRACT

A circuit board and a manufacturing method thereof are provided. The manufacturing method includes the following steps. A substrate having a first surface and a second surface opposite to each other is provided. A first circuit layer is formed on the first surface. A stress is applied to the first circuit layer and the substrate using a awl tool, such that the first circuit layer and the substrate are deformed to form a through hole. A portion of the first circuit layer is located on the sidewalls of the through hole and an end of the through hole is protruded from the second surface. A printing process is performed to form a second circuit layer on the second surface. The second circuit layer is connected to the first circuit layer located in the through hole.

### BACKGROUND

1. Field of the Application

The invention relates to a circuit board and a manufacturing method thereof, and more particularly, to a circuit board having a through hole formed by deforming a substrate, and a manufacturing method thereof.

2. Description of Related Art

In recent years, following the rapid changes in electronic technology and the successions of the high-tech electronic industry, more humane electronic products with better functions are continued to be introduced, and are designed toward the trends of being light, thin, short, and small. Within these electronic products, a circuit board having a circuit is usually disposed therein.

In general, when manufacturing the circuit board, a first conductive layer and a second conductive layer are firstly formed on two opposite surfaces of a substrate, respectively. Then, a through hole is formed in the conductive layers and the substrate. Next, a third conductive layer is formed in the through hole by an electroplating process to connect the first conductive layer and the second conductive layer. Afterward, the first conductive layer and the second conductive layer are patterned to form a first circuit layer and a second circuit layer.

However, the aforementioned manufacturing process of the circuit board has to go through the steps of electroplating, patterning and so forth, thereby increasing the process complexity and process time. In addition, when forming the through hole, a mechanical drilling or a laser drilling is conventionally used to form the through hole by removing a portion of the conductive layer and a portion of the substrate, and thus causes a consumption and waste of the conductive material.

### SUMMARY OF THE APPLICATION

The invention provides a manufacturing method of a circuit board, which uses an awl tool to deform the substrate to form a through hole.

The invention also provides a circuit board having a through hole with an end protruding from a surface of a substrate.

The invention provides a manufacturing method of a circuit board. Firstly, a substrate having a first surface and a second surface opposite to each other is provided. Then, a first circuit layer is formed on the first surface. Next, a stress is applied to the first circuit layer and the substrate using a awl tool, such that the first circuit layer and the substrate are deformed to form a through hole, wherein a portion of the first circuit layer is located on the sidewalls of the through hole, and an end of the through hole is protruded from the second surface. Afterward, a printing process is performed to form a second circuit layer on the second surface, wherein the second circuit layer is connected to the first circuit layer located in the through hole.

According to an embodiment of the manufacturing method of the circuit board, a method of applying the stress to the first circuit layer and the substrate, for example, is to use the awl tool to perforate the first circuit layer and the substrate.

The invention provides another manufacturing method of a circuit board. Firstly, a substrate having a first surface and a second surface opposite to each other is provided. Then, a stress is applied to the substrate using a awl tool, such that the substrate is deformed to form a through hole, wherein an end of the through hole is protruded from the second surface. Next, a first printing process is performed to form a first circuit layer on the first surface and on the sidewalls of the through hole. Afterward, a second printing process is performed to form a second circuit layer on the second surface, wherein the second circuit layer is connected to the first circuit layer located in the through hole.

According to an embodiment of the manufacturing method of the circuit board, a method of applying the stress to the substrate, for example, is to use the awl tool to perforate the substrate.

According to an embodiment of the manufacturing method of the circuit board, the awl tool, for example, is a needle.

The invention further provides a circuit board including a substrate, a first circuit layer and a second circuit layer. The substrate has a first surface and a second surface opposite to each other, and the substrate has a through hole therein, wherein an end of the through hole is protruded from the second surface. The first circuit layer is disposed on the first surface and on the sidewalls of the through hole. The second circuit layer is disposed on the second surface and connected to the first circuit layer located in the through hole.

According to an embodiment of the circuit board, the substrate, for example, is a dielectric substrate.

According to an embodiment of the circuit board, a material of the first circuit layer, for example, is copper or silver.

According to an embodiment of the circuit board, a material of the second circuit layer, for example, is copper or silver.

According to the foregoing, in the invention, after the first circuit layer is formed on the substrate, the through hole is formed by using the awl tool to perforate the first circuit layer and the substrate, instead of by removing a portion of the substrate and a portion of the first circuit layer; and therefore, a conductive material for manufacturing the first circuit layer is avoided from being wasted, and an objective of saving the material is achieved. In addition, in the invention, after the through hole is formed, the first circuit layer is already located on the sidewalls of the through hole; and therefore, no additional electroplating process is required to be performed for forming a conductive layer located on the sidewalls of the through hole to connect the two circuit layers, such that the manufacturing process and the process time are simplified.

Otherwise, in the invention, after the through hole is formed by using the awl tool to perforate the substrate, by using a printing method, the first circuit layer is directly formed on the first surface of the substrate and on the sidewalls of the through hole, and the second circuit layer is formed on the second surface of the substrate; therefore, no additional electroplating process is required to be performed for forming a conductive layer located on the sidewalls of the through hole to connect the two circuit layers, such that the manufacturing process and the process time are simplified.

In order to make the aforementioned and other features and advantages of the present application more comprehensible, several embodiments accompanied with figures are described in detail below.

### BRIEF DESCRIPTION OF THE DRAWINGS

The accompanying drawings are included to provide a further understanding of the application, and are incorporated in and constitute a part of this specification. The drawings illustrate embodiments of the application and, together with the description, serve to explain the principles of the application.

FIG. 1A through FIG. 1C are cross-sectional views schematically illustrating a manufacturing method of a circuit board according to a first embodiment of the invention.

FIG. 2A through FIG. 2C are cross-sectional views schematically illustrating a manufacturing method of a circuit board according to a second embodiment of the invention.

### DETAILED DESCRIPTION OF DISCLOSED EMBODIMENTS

### First Embodiment

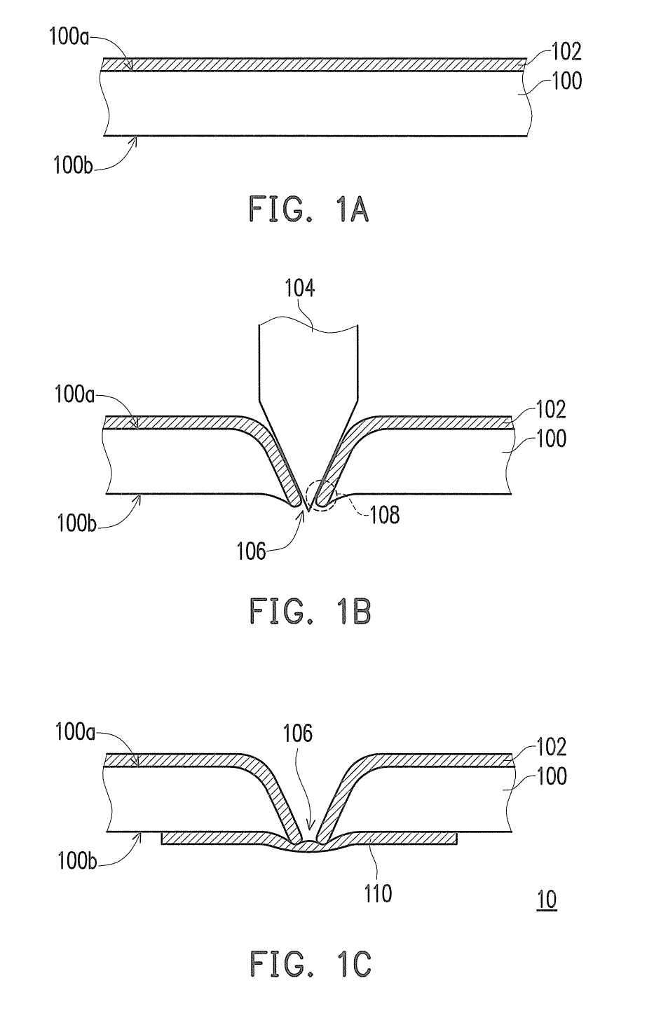

FIG. 1A through FIG. 1C are cross-sectional views schematically illustrating a manufacturing method of a circuit board according to a first embodiment of the invention. Firstly, referring to FIG. 1A, a substrate 100 is provided. The substrate 100, for example, is a dielectric substrate, which can be a polyethylene tetra phthalate (PET) thin film or a polyimide (PI) thin film. The substrate 100 has a first surface 100a and a second surface 100b opposite to each other. Then, a first circuit layer 102 is formed on the first surface 100a. A material of the first circuit layer 102, for example, is copper or silver. A method for forming the first circuit layer 102, for example, is a printing process. Or, the first circuit layer 102 may also be formed by performing an etching process to a copper foil.

Next, referring to FIG. 1B, a stress is applied to the first circuit layer 102 and the substrate 100 using a awl tool 104, such that the first circuit layer 102 and the substrate 100 are deformed to form a through hole 106. The awl tool 104, for example, is a needle. In detail, in this step, the awl tool 104 is used to perforate the first circuit layer 102 and the substrate 100 so as to form the through hole 106 in the first circuit layer 102 and the substrate 100.

In the present embodiment, since the awl tool 104 has only perforated the first circuit layer 102 and the substrate 100, instead of removing a portion of the substrate and a portion of the circuit layer to form a through hole by using the general mechanical drilling and laser drilling, a conductive material for forming the first circuit layer 102 may be avoided from being wasted. In addition, during the process of using the awl tool 104 to perforate the first circuit layer 102 and the substrate 100, since no portion of the first circuit layer 102 and the substrate 100 is removed, and the first circuit layer 102 and the substrate 100 are merely deformed, the first circuit layer 102 is still remained on the sidewalls of the resulting through hole 106. Therefore, after the through hole 106 is formed, no additional electroplating process is required to be performed for forming a conductive layer located on the sidewalls of the through hole 106, such that the manufacturing process and the process time are simplified and the production cost are lowered.

Particularly, in the present embodiment, since the awl tool 104 deforms the first circuit layer 102 and the substrate 100 to form the through hole 106, an end of the resulting through hole 106 neighboring the second surface 100b is protruded from the second surface 100b, for instance, shown as a region 108.

Afterward, referring to FIG. 1C, a printing process is performed, and a second circuit layer 110 is formed on the second surface 100b by using the printing process. A material of the second circuit layer 102, for example, is copper or silver. Since the first circuit layer 102 is located on the sidewalls of the through hole 106, the resulting second circuit layer 110 may be connected to the first circuit layer 102 located in the through hole 106, so as to complete the manufacturing of the circuit board 10 of the present embodiment.

### Second Embodiment

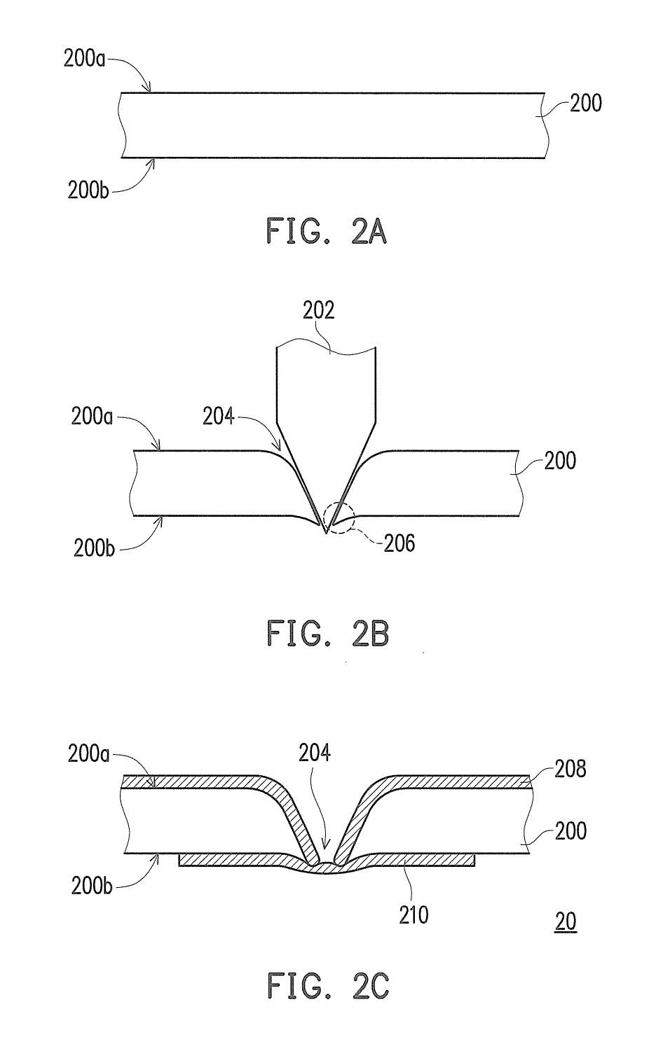

FIG. 2A through FIG. 2C are cross-sectional views schematically illustrating a manufacturing method of a circuit board according to a second embodiment of the invention. Firstly, referring to FIG. 2A, a substrate 200 is provided. The substrate 200, for example, is a dielectric substrate, which may be a polyethylene tetra phthalate thin film or a polyimide thin film. The substrate 200 has a first surface 200a and a second surface 200b opposite to each other.

Then, referring to FIG. 2B, a stress is applied to the substrate 200 using a awl tool 202, such that the substrate 200 is deformed to form a through hole 204. The awl tool 202, for example, is a needle. In detail, in this step, the awl tool 202 is used to perforate the substrate 200 so as to form the through hole 204 in the substrate 200.

Particularly, in the present embodiment, since the awl tool 202 deforms the substrate 200 to form the through hole 204, an end of the resulting through hole 204 neighboring the second surface 200b is protruded from the second surface 200b, for instance, shown as a region 206.

Afterward, by using a printing process, a first circuit layer 208 is formed on the first surface 200a and on the sidewalls of the through hole 204, and a second circuit layer 210b is formed on the second surface 200b. A material of the first circuit layer 208 and the second circuit layer 210, for example, is copper or silver. Since the first circuit layer 208 is located on the sidewalls of the through hole 204, the resulting second circuit layer 210 may be connected to the first circuit layer 208 located on the through hole 204, so as to complete the manufacturing of the circuit board 20 of the present embodiment. In the present embodiment, the first circuit layer 208 may be printed on the first surface 200a and on the through hole 204 before the second circuit layer 210 is printed on the second surface 200b, but the invention is not limited thereto. Namely, the second circuit layer 210 may also be printed on the second surface 200b before the first circuit layer 208 is printed on the first surface 200a.

In the present embodiment, after the through hole 106 is formed by using the awl tool 202 to perforate the substrate 100, by using the printing method, the first circuit layer 208 is directly formed on the first surface 200a and on the sidewalls of the through hole 204, the second circuit layer 210 is formed on the second surface 200b, and the second circuit layer 210 may be directly connected to the first circuit layer 208 in the through hole 204; therefore, no additional electroplating process is required to be performed for forming a conductive layer located on the sidewalls of the through hole, such that the manufacturing process and the process time are simplified, and the production cost is lowered.

It will be apparent to those skilled in the art that various modifications and variations can be made to the structure of the application without departing from the scope or spirit of the application. In view of the foregoing, it is intended that the application cover modifications and variations of this application provided they fall within the scope of the following claims and their equivalents.

What is claimed is:

1. A manufacturing method of a circuit board, comprising:
providing a substrate, the substrate having a first surface and a second surface opposite to each other;
forming a first circuit layer on the first surface;
using a awl tool to apply a stress to the first circuit layer and the substrate, such that the first circuit layer and the substrate are deformed to form a through hole, wherein a portion of the first circuit layer is located on sidewalls of the through hole, and an end of the through hole is protruded from the second surface; and
performing a printing process to form a second circuit layer on the second surface, wherein the second circuit layer is connected to the first circuit layer located in the through hole.

2. The manufacturing method of the circuit board as recited in claim 1, wherein a method of applying the stress to the first circuit layer and the substrate comprises using the awl tool to perforate the first circuit layer and the substrate.

3. The manufacturing method of the circuit board as recited in claim 1, wherein the awl tool comprises a needle.

4. A manufacturing method of a circuit board, comprising:
providing a substrate, the substrate having a first surface and a second surface opposite to each other;
using a awl tool to apply a stress to the substrate, such that the substrate is deformed to form a through hole, wherein an end of the through hole is protruded from the second surface;
performing a first printing process to form a first circuit layer on the first surface and on sidewalls of the through hole; and
performing a second printing process to form a second circuit layer on the second surface, wherein the second circuit layer is connected to the first circuit layer located in the through hole.

5. The manufacturing method of the circuit board as recited in claim 4, wherein a method of applying the stress to the substrate comprises using the awl tool to perforate the substrate.

6. The manufacturing method of the circuit board as recited in claim 4, wherein the awl tool comprises a needle.

7. A circuit board, comprising:
a substrate, having a first surface and a second surface opposite to each other, and the substrate has a through hole therein, wherein an end of the through hole is protruded from the second surface;
a first circuit layer, disposed on the first surface and on sidewalls of the through hole; and
a second circuit layer, disposed on the second surface and connected to the first circuit layer located in the through hole.

8. The circuit board as recited in claim 7, wherein the substrate comprises a dielectric substrate.

9. The circuit board as recited in claim 7, wherein a material of the first circuit layer comprises copper or silver.

10. The circuit board as recited in claim 7, wherein a material of the second circuit layer comprises copper or silver.
